(19) United States
(12) Patent Application Publication
(10) Pub. No.: US 2016/0054365 A1
(43) Pub. Date: Feb. 25, 2016

(54) ELECTRICAL CONTROLS FOR TESTING A TRAILER SYSTEM

(71) Applicant: Greif Packaging LLC, Delaware, OH (US)

(72) Inventors: Scott M. Cooper, Massillon, OH (US); Mark S. Yerrick, Canton, OH (US); Raymond Shelton, Akron, OH (US)

(73) Assignee: Greif Packaging LLC

(21) Appl. No.: 14/464,050

(22) Filed: Aug. 20, 2014

(51) Int. Cl. G01R 31/00; G07C 5/00; G01R 31/44; B60R 16/03

(52) U.S. Cl. CPC G01R 31/006; B60R 16/03; G07C 5/008; G01R 31/44

(57) ABSTRACT

A system is disclosed for testing electrical devices on a trailer without a truck being connected to the trailer. The system includes a control cable and a test control box. When an operator activates the test system, the box selectively powers a number of different electrical devices on the trailer through the control cable. As the different devices are powered up, the operator is able to physically inspect the trailer to be sure that each device works or does not work. The system may include one or more closed circuit cameras and a display screen operatively engaged therewith. Each camera is positioned to capture an image of one of the electrical devices and to transmit that image to the display screen where it is viewable by the operator. The cameras and screen allow the operator to remain in a single location while testing all of the devices on the trailer.

### BACKGROUND OF THE INVENTION

1. Field of Invention

The current invention relates generally to apparatus, systems and methods for testing electrical components. More particularly, the apparatus, systems and methods relate to testing electrical components on a trailer. Specifically, the apparatus, systems and methods provide for testing whether electrical devices such as turn signals, brake lights, and hazard lights on a trailer are operational when that trailer is not connected to a truck.

2. Description of Related Art

Companies often own a fleet of trailers that are towed by trucks. These trailers have a variety of lights that perform different functions. When the trailer is connected to a truck, a standardized cable from the trailer is plugged into the truck. This cable supplies power to the trailer's lights and also has wires used to control the trailer lights from the truck.

There are often a variety of lights on a trailer. Sometimes there are other electronically controlled devices mounted on a trailer such as electronic braking controls. For example, left and right turn signal lights are used to indicate that a truck that is attached to a trailer is going to make a turn. Brake lights on the rear of the trailer indicate that the trailer is braking. Electronic signals from an anti-lock braking system (ABS) computer control an ABS brake system. Marker lights indicate the outer edges of a trailer. Four-way lights (e.g., hazard) lights indicate that the truck may be creating a hazardous condition by driving slowly up a mountain or sitting stationary alongside a road.

As described above, trailers have a variety of lights as well as other electric signals that are important to the safety of the truck, its trailer and others. Often companies have so many trailers that it is very time consuming to periodically test and check all of these different lights and electronic signals. It is difficult to bring a truck and trailer into a testing center so that the truck may be used to operate the different lights and the electronic ABS of the trailer so that they may be checked to be sure they are all operational. Additionally, two people are required to perform this check, namely, a driver of the truck and a person performing the test. What is needed is a better way of testing trailer lights and other electronic devices on trailers.

### SUMMARY

A system is disclosed for testing electrical devices on a trailer without a truck being connected to the trailer. The system includes a control cable and a test control box. When an operator activates the test system, the box selectively powers a number of different electrical devices on the trailer through the control cable. As the different devices are powered up, the operator is able to physically inspect the trailer to be sure that each device works or does not work. The system may include one or more closed circuit cameras and a display screen operatively engaged therewith. Each camera is positioned to capture an image of one of the electrical devices and to transmit that image to the display screen where it is viewable by the operator. The cameras and screen allow the operator to remain in a single location while testing all of the devices on the trailer.

One aspect of an embodiment of the invention may include a system for testing electrical devices on a trailer without a truck being connected to the trailer. A trailer test system includes a control cable and a test control box. The test control box powers electrical devices on the trailer through the control cable. The test control box powers up different electrical devices on the trailer when controlled to do so by a person using the trailer test system, i.e., the operator, without a truck needing to be connected to the trailer. As the different electrical devices are powered up, the operator may inspect the trailer to be sure that each device works or does not work.

In another aspect the invention may provide a method for testing a trailer. The method begins by connecting a test control box to a trailer without a truck being connected to the trailer. An electronic device on the trailer is tested with the test control box to be sure the electronic device is functional. This testing is performed without a truck required to be connected to the trailer to power the trailer. Instead the electronic device is powered by the test control box.

### BRIEF DESCRIPTION OF SEVERAL VIEWS OF THE DRAWINGS

The accompanying drawings, which are incorporated in and constitute a part of the specification, illustrate various example methods, and other example embodiments of various aspects of the invention. It will be appreciated that the illustrated element boundaries (e.g., boxes, groups of boxes, or other shapes) in the figures represent one example of the boundaries. One of ordinary skill in the art will appreciate that in some examples one element may be designed as multiple elements or that multiple elements may be designed as one element. In some examples, an element shown as an internal component of another element may be implemented as an external component and vice versa. Furthermore, elements may not be drawn to scale.

FIG. 1 illustrates a perspective view of a trailer testing system and a trailer to be tested thereby; which trailer is not connected to a truck.

FIG. 2 illustrates a back view of the trailer being tested by the trailer testing system.

FIG. 3 illustrates a perspective view of a test control box of the trailer testing system.

FIG. 4 illustrates an example wiring schematic of the trailer testing system.

FIG. 5 illustrates an example plug of the trailer testing system.

FIG. 6 illustrates an example of a method for testing a trailer without a truck needing to be connected to the trailer.

Similar numbers refer to similar parts throughout the drawings.

### DETAILED DESCRIPTION

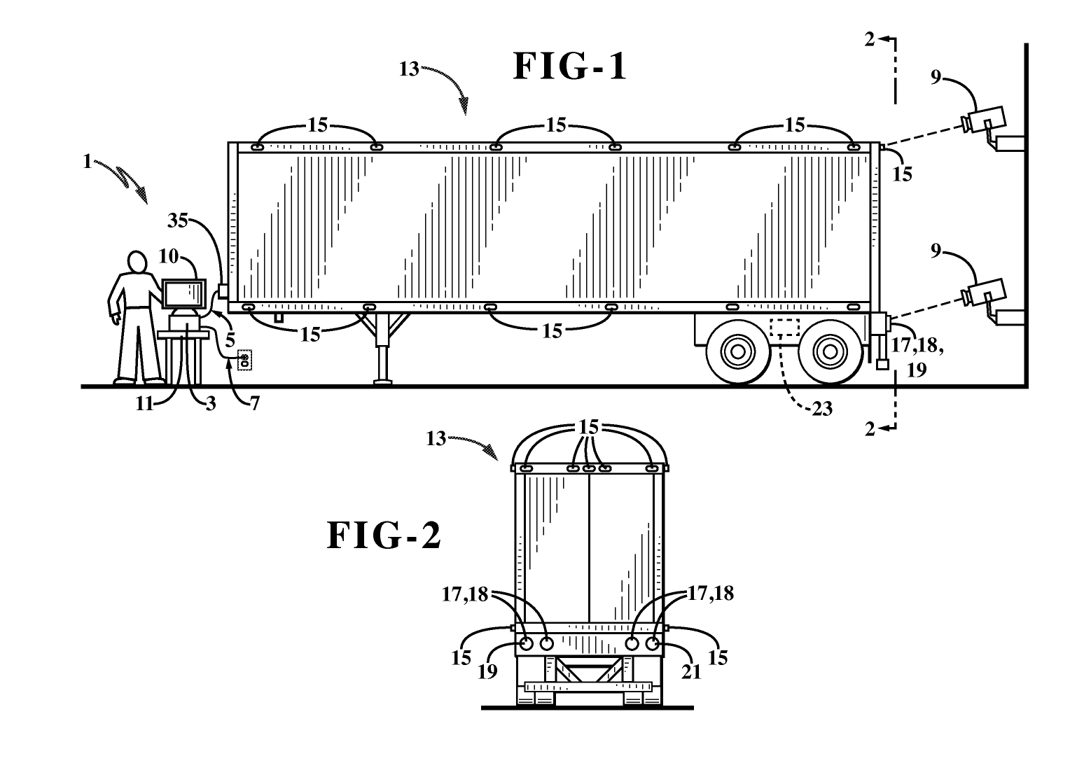

FIG. 1 illustrates a trailer test system 1 that is utilized on a trailer 13 when the trailer is not connected to a truck. The trailer test system 1 powers the electronic system on the trailer 13 to enable the testing of various electronic devices on trailer 13.

The trailer test system 1 includes a test control box 3, a control cable 5, and a power cable 7. System 1 may further include one or more closed circuit cameras 9 and a display screen 10. In example FIG. 1, the test control box 3 is illustrated sitting on a bench 11 and screen 10 is mounted on box 3. In other instances, not illustrated herein, test control box 3 may be a handheld device so that the operator may physically walk around trailer 13 that is being tested in order to visually verify if the electrical devices being activated on the trailer are working.

In the instance where cameras 9 and display screen 10 are utilized, the operator may remain in a single location and remotely test all of the electrical devices on the trailer 13, as will be hereafter described. The display screen 10 is operatively engaged with cameras 9 and receives feed therefrom. Display screen 10 is positioned so that it is readily seen by the operator. Screen 10 may form part of the test control box 3 or may be a separate component that is positioned on bench 11. The cameras 9 are strategically placed in order to capture an image of various electrical devices, such as the brake lights and turn signals on the rear of the trailer 13, and to transmit that image to the remote display screen 10 where the image is able to be easily viewed by the operator.

The power cable 7 is connected between the test control box 3 and a power outlet to supply power to the test control box 3. In other configurations, the test control box 3 may be battery powered to make it more mobile.

FIGS. 1 and 2 show an example of the various electrical devices of a typical trailer 13 which may be tested with system 1. Trailer 13 includes marker lights 15 which may define the outside edges of the trailer 13. Trailer 13 also includes brake lights 17, tail lights 18 (e.g., 4-way tail lights), a left turn light 19 and a right turn light 21. The left turn light 19 and the right turn light 21 may also function as brake lights 17 and tail lights 18 via a 4-way plug. Trailer test system 1 may also includes the ability to test one or more anti-locking brake system (ABS) computers 23 of the trailer 13 that control the braking system of the trailer 13.

It will be understood that other trailers may have lights and electronic devices that are in different configurations from that shown in the attached figures and that the system 1 may be used with these differently configured trailers in a similar manner to that described herein.

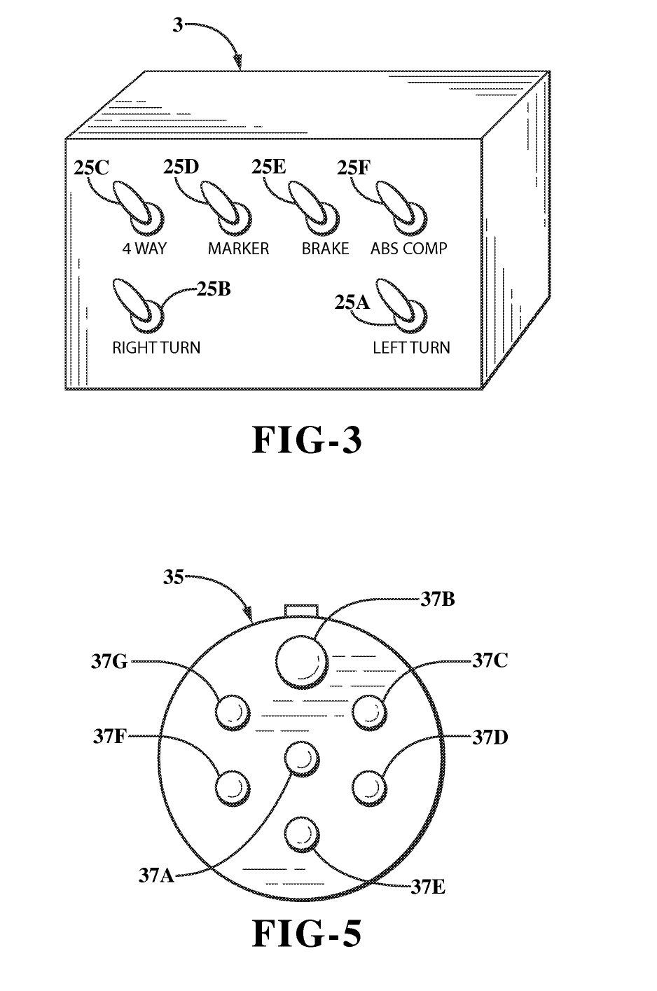

FIG. 3 illustrates an example of the test control box 3 which forms part of system 1. Box 3 is shown without display screen 10 engaged therewith. Control box 3 includes various switches for selectively activating each of the lights 15, 17, 18, 19, 21, and/or electronic components 23 of the trailer 13 so that they may be tested. These switches are illustrated as toggle switches but they may be any type of switch as understood by those of ordinary skill in the art. For example, a left turn switch 25A and a right turn switch 25B on control box 3 may be used to activate, respectively, the left turn light 19 and the right turn light 21 on trailer 13. Similarly, a “4-way” switch 25C on control box 3 may be used to activate the tail lights 18 on trailer 3; a marker switch 25D on control box 3 may be used to activate the marker lights 15 on trailer 13; and a brake switch 25E on control box 3 may be used to activate the brake lights 17 on trailer 13. An ABS computer switch 25F on control box 3 may be used to activate the ABS computer 23 of the trailer 13.

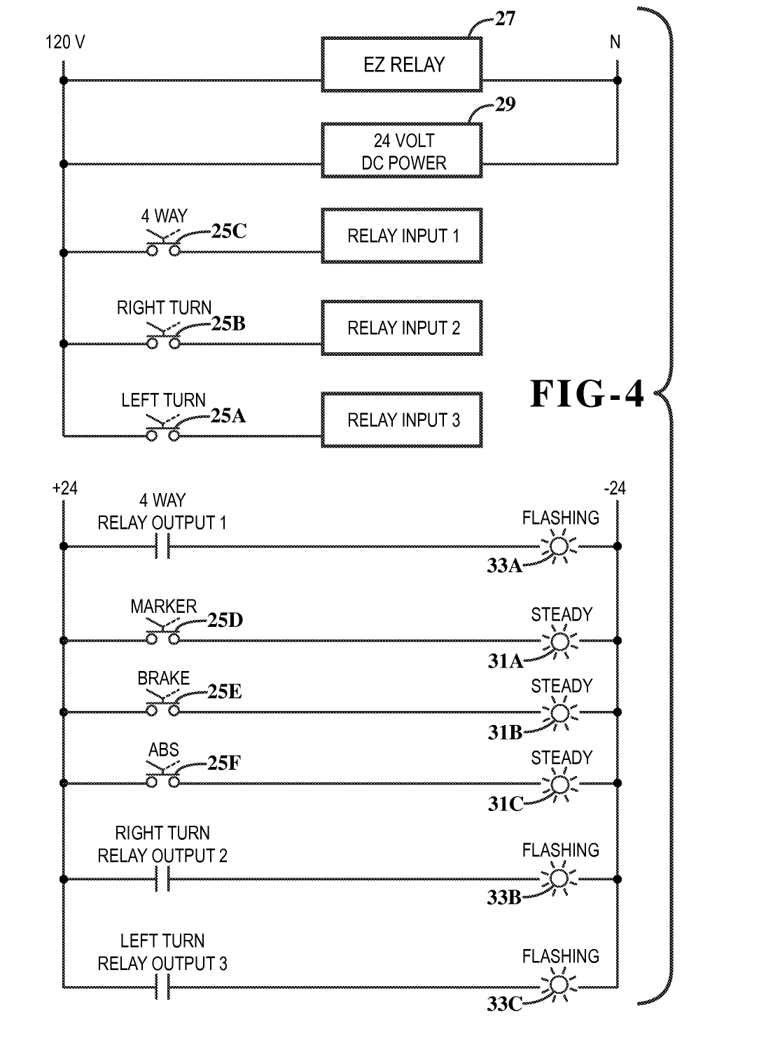

FIG. 4 illustrates some example wiring of the trailer testing system 1. As illustrated, some components of the trailer 13 may need higher power and/or current to be tested. For these components relays provided in control box 3 may be used. For example, relay 1 is used to control the tail lights 18, relay 2 is used to control the right turn signal 21 and relay 3 is used to control the left turn signal 19. These relays may all be located in an Eaton EASY type of programmable relay type of system. For example, these relays could be implemented in an Eaton EASY500 device 27. The trailer test system 1 may also include a 24 volt DC power supply 29. Of course, in other embodiments other power supplies with different voltages may be used such as a 12 volt Siemens power supply. As illustrated, steady lights 31A-C are used to respectively indicate the marker lights 15, the brake lights 17 and the ABS computer 23 of the trailer. Flashing lights 33A-C are used to respectively indicate the tail lights 18, the right turn light 21 and the left turn light 19. In other embodiments, these lights 31A-C and 33A-C could be indicator lights on the test control box 3 that indicate which lights 15, 17, 18, 19, and 21 on the trailer 13 are currently being tested.

FIG. 5 illustrates an example of a trailer plug 35 that may be used with the test control box 3 of FIG. 3 and the wiring of FIG. 4. The trailer plug 35 connects to a complementary plug on the trailer 13 as illustrated in FIG. 1. An ABS computer plug 37A (FIG. 5) is located at the center of the trailer plug 35. The ABS computer plug 37A is surrounded by a ground plug 37B, a marker light plug 37C, a left turn light plug 37D, a brake light plug 37E, a right turn light plug 37F and a 4-way (tail light or hazard light) plug 37G.

Having described the components of the trailer testing system 1, its use and operation are now described. Initially, the trailer 13 is pulled by a truck to a location where the trailer testing system 1 is located or alternatively the trailer testing system 1 is transported to the trailer 13. The trailer testing system 1 is, if necessary, plugged into a power source to receive power through its power cable 7. Control box 3 is operatively engaged with the electronic system of trailer 13 via control cable 5 by engaging trailer plug 35 into a complementary socket on trailer 13.

Testing the lights and electronic devices of the trailer 13 is now a simple matter of flipping the switches 25A-F of the test control box 1 and observing the various activated lights and systems on the trailer 13 for a response. For example, activating the left turn switch 25A on control box 3 should cause the left turn light 19 to blink. An operator of the trailer testing system 1 would either physically observe the left turn light 19 to see if it is activated or the operator will look into display screen 10 to see if the left turn light 9 is blinking. If the left turn light 19 is working, the light 19 has passed the test and the operator will move to the next light or component to be tested. If left turn light 19 does not work then the operator may troubleshoot the cause and repair that light. The left turn switch 25A on the control box is turned off when the testing of the associated left turn light 19 is complete. A similar test may then be made for the right turn light 21 using the right turn switch 25B.

The marker switch 25D on control box 3 may be turned on to activate the marker lights 15. The operator could use the cameras 9 and display screen 10 to verify whether marker lights 15 are operational. Alternatively, the operator may walk to the left and right sides of the trailer 13 to visually inspect the marker lights 15 to be sure they are working. When that test is complete, the marker switch 25D on control box 3 s turned off. The brake lights and tail lights (4-way lights and/or hazard lights) 17, 18, may be tested using the brake light switch 25E and 4-way switch 25D on the control box 3.

The ABS computer 23 is activated by turning on the ABS computer switch 25F on control box 3. This will cause the brake system of the trailer to activate. When the brake system activates, the operator of the trailer testing system 1 may hear and/or observe movements of the brake system of the trailer 1 to confirm that the ABS computer 23 is operational. Of course, the lights and ABS computer may be inspected as being operational in other ways as understood by those of ordinary skill in this art.

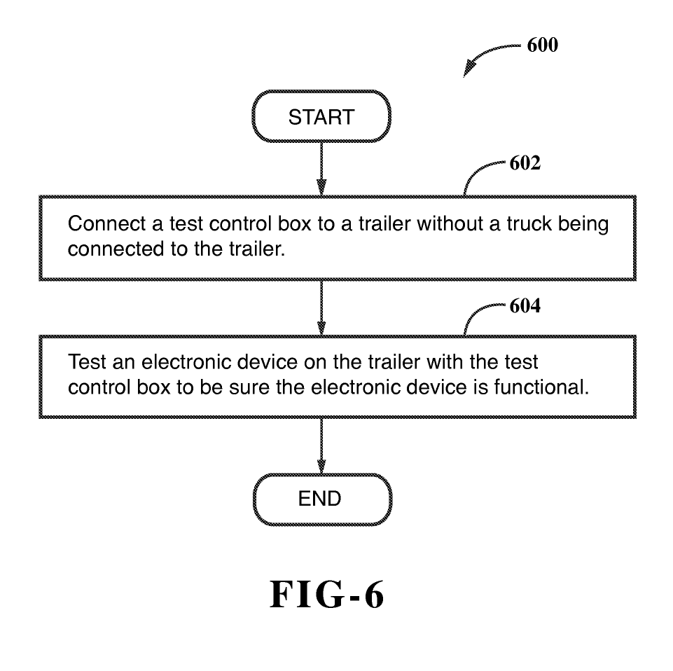

Example methods may be better appreciated with reference to the flow diagram of FIG. 6. While for purposes of simplicity of explanation, the illustrated methodologies are shown and described as a series of blocks, it is to be appreciated that the methodologies are not limited by the order of the blocks, as some blocks may occur in different orders and/or concurrently with other blocks from that shown and described. Moreover, less than all the illustrated blocks may be required to implement an example methodology. Blocks may be combined or separated into multiple components. Furthermore, additional and/or alternative methodologies may employ additional, not illustrated blocks.

FIG. 6 illustrates a method 600 of testing a trailer. The method 600 begins by connecting a test control box 3 to a trailer 13, at 602, without a truck being connected to the trailer. This step is accomplished by connecting the control box to the electronic system (not shown) of the trailer 13 by engaging a plug 35 on the end of a cable 5 with a complementary plug on the trailer 13. Once the control box 3 is operatively engaged with the electronics of trailer 13, an electronic device on the trailer 13 is tested with the test control box, at 604, to be sure the electronic device is functional. This testing is performed without a truck being connected to the trailer to power the trailer. Instead the electronic device is powered by the test control box 3. As discussed above, the electronic device test may be, for example, a left turn signal light 19, a right turn signal light 21, marker lights 15, a tail light 18, a brake light 17 and/or a brake computer 23.

The step of testing the electronic device includes the sub-steps of selecting a specific one of the of electronic devices 15-23 on the trailer to test; moving an associated switch 25A-25F on the control box 3 from a first position to a second position to activate the selected electronic device; determining if the selected electronic device is functioning; and then moving the associated switch on the control box 3 from the second position back to the first position.

The method further includes selecting a second one of the electronic devices 15-23 on the trailer to test; moving an associated second switch 25A-25F on the control box 3 from a first position to a second position to activate the selected second electronic device; determining if the selected second electronic device is functioning; and then moving the associated second switch on the control box from the second position to the first position. The step of determining if the selected electronic device or second electronic device is functioning is accomplished by walking to a position adjacent the selected electronic device and physically checking if a light in the device is on or not. Alternatively, the step of determining if the device is functioning is accomplished by viewing a display screen to see if the image on the screen shows that a light in the device is on or not.

The method further includes determining that a particular selected electronic device is failing to function; troubleshooting the reasons for that failure to function; and repairing the non-functioning electronic device; and then retesting the particular electronic device to ensure that device is now functioning.

The aforementioned methodology is used for each of the individual electronic devices to be tested and once all of the tested electronic devices are functioning, the method includes detaching the control box 3 from trailer 13 by disengaging plug 35 from the complementary plug on the trailer 13.

In the foregoing description, certain terms have been used for brevity, clearness, and understanding. No unnecessary limitations are to be implied therefrom beyond the requirement of the prior art because such terms are used for descriptive purposes and are intended to be broadly construed. Therefore, the invention is not limited to the specific details, the representative embodiments, and illustrative examples shown and described. Thus, this application is intended to embrace alterations, modifications, and variations that fall within the scope of the appended claims.

Moreover, the description and illustration of the invention is an example and the invention is not limited to the exact details shown or described. References to “an embodiment”, “one example”, “an example”, and so on, indicate that the embodiment(s) or example(s) so described may include a particular feature, structure, characteristic, property, element, or limitation, but that not every embodiment or example necessarily includes that particular feature, structure, characteristic, property, element or limitation.

What is claimed is:

1. A trailer test system comprising:
a control cable; and
a test control box adapted to power electrical devices on a trailer through the control cable, wherein the test control box is adapted to selectively power up different electrical devices on the trailer when controlled to do so by a operator of the trailer test system without a truck being connected to the trailer.

2. The trailer test system of claim 1 wherein the test control box is adapted to power at least one of the group of: a left turn signal light, a right turn signal light, marker lights, a tail light, 4-way hazard lights, a brake light and a brake computer.

3. The trailer test system of claim 1 further comprising:
at least one camera strategically placed with reference to the electrical device to be tested so as to capture an image of that electrical device; and
a display screen operatively engaged with the at least one camera, said display screen being located so that the operator is able to view an image of the electrical device on the display screen.

4. The trailer test system of claim 1 where the test control box further comprises:
switches to selectively activate one or more of the electrical devices.

5. The trailer test system of claim 4 wherein the switches further comprise:
toggle switches.

6. The trailer test system of claim 1 further comprising:
a power cord adapted to be connected to the test control box and to supply power to the test control box.

7. The trailer test system of claim 6 wherein the power cord supplies 12 or 24 volts of power to the test control box.

8. The trailer test system of claim 1 further comprising:
a trailer plug at one end of the control cable adapted to plug into a complementary plug on the trailer.

9. The trailer test system of claim 8 wherein the trailer plug further comprises:
an anti-lock brake system (ABS) connector located at a center of the trailer plug.

10. The trailer test system of claim 9 further comprising:
a ground connector located between an outside edge of the trailer plug and the ABS connector.

11. The trailer test system of claim 1 further comprising:
a relay adapted to alter an electrical signal from the control box to at least one of the electrical devices to be tested.

12. The trailer test system of claim 11 wherein the relay further comprises:
a programmable relay.

13. The trailer test system of claim 11 wherein the relay further comprises:
an Eaton EASY 500 relay.

14. The trailer test system of claim 1 further comprises:
a battery to power the control box.

15. A method for testing a trailer comprising:
connecting a test control box to a trailer; and
testing an electronic device on the trailer with the test control box to be sure the electronic device is functional, and wherein the testing is performed when the trailer is not connected to a truck and is therefore not powered by a truck.

16. The method of claim 15 wherein the testing of the electronic device includes selectively testing one of more or the group of:
a left turn signal light, a right turn signal light, marker lights, a tail light, a brake light and a brake computer.

17. The method of claim 15 further comprising:
looking at display screen operatively connected to a strategically placed camera focused on the electronic device to verify whether the electronic device is functional.

18. The method of claim 15 further comprising:
connecting a control cable between the test control box and the trailer.

19. The method of claim 15 further comprising:
controlling a selected electronic device on the trailer through a relay in the test control box.

20. The method of claim 15 further comprising:
controlling a selected electronic device on the trailer through a programmable relay in the test control box.
